(19) United States
(12) Patent Application Publication
(10) Pub. No.: US 2014/0334103 A1
(43) Pub. Date: Nov. 13, 2014

(54) COOLED ELECTRIC UNIT

(71) Applicant: Rogers Germany GmbH, Eschenbach (DE)

(72) Inventors: Jurgen Schulz-Harder, Lauf (DE); Andreas Meyer, Wenzenbach (DE)

(21) Appl. No.: 14/339,856

(22) Filed: Jul. 24, 2014

Related U.S. Application Data
(62) Division of application No. 13/322,765, filed on Nov. 28, 2011.

(30) Foreign Application Priority Data
May 27, 2009 (DE) DE102009022877.2

(51) Int. Cl. H05K 7/20; H01L 23/373

(52) U.S. Cl. CPC H05K 7/20509; H01L 23/3736
USPC 361/702

(57) ABSTRACT

An electric unit having at least one cooler structure and at least one electric module with at least one electric element on a metal-ceramic substrate.

### BACKGROUND OF THE INVENTION

The invention refers to a cooled electric or electronic unit.

DCB (Direct Copper Bond) technology is used to bond metal layers or sheets (e.g. copper sheets or foils) with each other and/or with ceramic or ceramic layers using metal or copper sheets or metal or copper foils, which are provided on their surfaces with a layer or coating (hot-melt layer) resulting from a chemical reaction between the metal and a reactive gas, preferably oxygen. In this method, which is described, for example, in U.S. Pat. No. 3,744,120 and in DE-PS 23 19 854, this layer or coating (hot-melt layer) forms a eutectic with a melting temperature below the melting temperature of the metal (e.g. copper), so that the layers can be bonded to each other by placing the foil on the ceramic and heating all layers, by melting the metal or copper essentially only in the area of the hot-melt layer or oxide layer. This DCB method comprises, for example, the following steps:
oxidation of a copper foil so as to produce an even copper oxide layer;
placing the copper foil on the ceramic layer;
heating the composite to a process temperature between approximately 1023 and 1083° C., e.g. to approximately 1071° C.; and
cooling to room temperature.

Active soldering or AMB process (DE 22 13 115, EP-A-153 618) is used for bonding of metal layers or metal foils forming metallizations, especially of copper layers or copper foils, with a ceramic material. In this process, which is used especially for manufacturing a metal-ceramic substrate, a bond is produced at a temperature of ca. 800° C.-1000° C. between a metal foil, for example a copper foil, and a ceramic substrate, for example an aluminum-nitride ceramic, using a hard solder, which in addition to a main solder component such as copper, silver and/or gold also contains an active metal. This active metal, which is at least one element of the group Hf, Ti, Zr, Nb, Ce, creates a bond between the solder and the ceramic through a chemical reaction, while the bond between the solder and the metal is a metallic hard solder bond.

Also known are methods for producing metallizations, especially in the form of strip conductors, contact surfaces, etc. in thick film technology (thick layer technology), in which a paste containing the metallization is applied to the insulating substrate (ceramic layer) by means of the screen resist method and then fired by heating.

Also known are cooled electric or electronic units, which in the simplest case consist of one electric or electronic module and one cooler, for example an active cooler.

Electric or electronic modules according to the invention are simple or complex electronic circuits or circuitries consisting at least of metal-ceramic substrates and respectively with at least one electric or electronic component, also a power component, e.g. semiconductor component, such as diode, transistor, IGBT or thyristor, etc.

Active coolers according to the invention are coolers with at least one cooling channel through which a gaseous, vaporous or fluid coolant (e.g. water with or without additives) can flow.

It is an object of the invention to present an electric or electronic unit that ensures optimal cooling of at least one module and of at least one electric or electronic component, the at least one power component and is cost-effectively produced.

### SUMMARY OF THE INVENTION

In a further embodiments of the invention the electric unit is designed so that the ceramic layers of the metal-ceramic substrates are provided on the surface side facing away from the first metallization with a second metallization and are connected by means of this second metallization by means of a thermally conductive intermediate layer at least thermally with the respective cooler. The first metallization of a metal-ceramic substrate is provided with external electrical connections, which protrude over the outer surface of the module, and the electrical connections are leads connected with the first metallization, for example, leads consisting of a leadframe. For creating the electrical connections, the ceramic layer of at least one metal-ceramic substrate, leads out at least with the structured first metallization through the outer surface or outer contour of the module or of the electric unit and that in the proximity of the connection on the side of the ceramic layer facing away from the first metallization, a metal surface is provided and this metal surface is mechanically connected with the first metallization by means of a metal through-hole contact. In addition, the ceramic layer in the proximity of the connection is provided with a breaking point or a continuous slot, and in the case of the at least one module being designed as a power module, at least all external electric power connections are provided on a single metal-ceramic substrate and protrude over a common side of the electric unit and/or of the module. The cooler structure comprises at least three coolers, which are arranged parallel to one another and at a distance from one another, and that between two coolers at least one module is provided which is connected at least thermally with both adjacent coolers on two mutually opposing sides of the module, and the coolers are connected with each other by means of spacers. Openings are provided at least in some spacers and they supplement openings in the coolers to form channels for the supply and return flow of the coolant. The coolers forming the cooler structure are multi-layered, consisting of several plates connected with each other on the surface, and the coolers are formed at least partially from a flat profile with a plurality of the cooling channels. The cooler structure comprises at least two chambers formed from pipe sections and at least two flat coolers extending between said chambers, the cooling channels of which (flat coolers) are connected with the chambers, and the chambers are provided with their longitudinal extension perpendicular or crosswise to the surface sides of the flat coolers, and at least two modules are connected to form a chamber-like modular unit that can be pushed onto the coolers of the cooler structure, and the coolers are flat, plate-shaped coolers.

The coolers have micro or macro cooling channels, the cooling channels constantly branching in several spatial axes, possibly with posts and are surfaces or wings transferring heat into the cooling channels. The coolers of the cooler structure are identical in design. The metal-ceramic substrates, for forming electrical connections, lead out of the modular unit (16b) on common or different sides, and the metal-ceramic substrates of at least one module are provided on at least one side of the module with sections protruding over this side, and these sections of the metal-ceramic substrates are mutually offset in an axis direction parallel to the surface sides of the substrates. At least one cooler of the flat profile is manufactured from a metal material, for example from copper, from a copper alloy, from aluminum, from an aluminum alloy or from plastic, for example from a plastic with an additive improving the thermal conductivity, e.g. in the form of graphite or carbon nanofiber material. The cooling channels lead on both ends into a chamber formed by a pipe section.

The cooler element and the cover are manufactured from aluminum, aluminum alloy or plastic, preferably with a filler improving the thermal conductivity. The cover is likewise tub-shaped in design, preferably identical to the tub-shaped cooler element or is designed as a flat cover. The cover and the cooler element are connected with each other by adhesive bonding, preferably using a thermally conductive adhesive. The cooler element is manufactured as a formed part or by machining. The at least one module is mounted on the outer side of the bottom, and the electric module or its metal-ceramic substrate is connected with the respective cooler by means of at least one intermediate layer. The intermediate layer is formed by a metal, for example solder, by a thermally conductive adhesive or by a thermally conductive paste. The intermediate layers are a solder intermediate layer and a solder layer, and the intermediate layers are an adhesive intermediate layer and a layer of a thermally conductive adhesive.

The ceramic layer is a layer of Al₂O₃, Al₂O₃+ZrO₂, AlN and/or Si₃N₄, and the respective ceramic-metal substrate is manufactured using AMB, DCB and/or DAB technology. The ceramic layer of the metal-ceramic substrate has a thickness between 0.15 and 2.0 mm, and the at least one metallization is made of copper, a copper alloy, an aluminum or an aluminum alloy and has a thickness between 0.012 and 0.8 mm. The at least one metallization consists of one or more layers of Ag, Ag—Pd, Ag—Pt, W/Ni, Mo—Mn/Ni and has a thickness of 0.01-0.9 mm. The solder intermediate layer consists of Ni, Cu or NiP and is applied by cold spraying, plasma spraying or flame spraying. The adhesive intermediate layer consists of Al₂O₃ and has a thickness of 0.01-0.1 mm, and the solder layer consists of Sn, Pb, Bi, In alloys or of AG and has a thickness of 0.02-0.5 mm. The solder intermediate layer consists of a metal material with an expansion coefficient of 7-12 ppm and is, for example, CuW or CuMo.

In the case of a substrate bonded to a cooler by at least one intermediate layer, the thickness of the cooler wall adjacent to the intermediate layer is so small that temperature-related mechanical tensions are compensated by the elasticity of the cooler wall and are kept away from or at least kept away to the greatest extent possible from the at least one intermediate layer. A thickness of the cooler wall is between 0.2 mm and 1.5 mm, and all of the above characteristics can be provided individually or in any combination.

Further embodiments, advantages and applications of the invention are also disclosed in the following description of exemplary embodiments and the drawings.

### BRIEF DESCRIPTION OF THE DRAWINGS

The invention is described in more detail below based on exemplary embodiments, in which:

FIG. 1 is a simplified schematic representation in cross section of an electric or electronic unit according to the invention;

FIG. 2-5 respectively are component drawings in cross section of different connections (terminals) of the unit of FIG. 1;

FIG. 6 shows in a representation similar to FIG. 1 a further embodiment of the unit according to the invention;

FIG. 7 is a top view of the unit of FIG. 6;

FIG. 8 shows in a perspective partial representation a possible embodiment of an active cooler for use in the unit of FIGS. 1 and/or 6 and 7;

FIGS. 9 and 10 show in a partial representation in top view an active cooler structure for use in the unit according to the invention;

FIG. 11 shows in a perspective representation the elements of the cooler structure of FIGS. 9 and 10, together with a modular unit comprising a plurality of modules;

FIG. 12 is a top view of an electric or electronic unit with a flat cooler formed by a flat profile; FIG. 13 shows the electronic unit of FIG. 12 in cross section;

FIG. 14 shows in a perspective exploded view a flat cooler for use in an electric or electronic unit according to the invention;

FIG. 15 shows a view similar to FIG. 1 of a further possible embodiment;

FIG. 16 shows a top view of a metal-ceramic substrate of an electronic unit according to the invention; and

FIG. 17 shows in a simplified cross section view a flat cooler for use in an electric or electronic unit according to the invention.

### DETAILED DESCRIPTION OF THE INVENTION

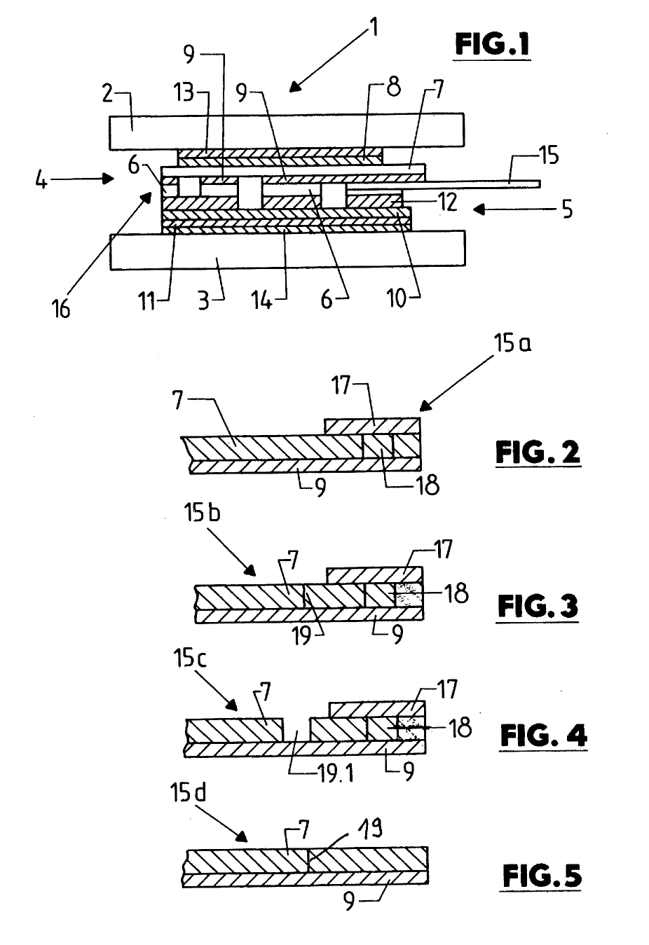

The electric unit generally designated 1 in FIG. 1 consists essentially of two external flat, plate-shaped coolers 2 and 3 forming a cooler structure, which (coolers) in the depicted embodiment are embodied designed as active coolers, i.e. as coolers through which a coolant can flow, for example as liquid coolers, of two metal-ceramic substrates 4 and 5 and of several electric or electronic components 6.

The metal-ceramic substrate 4, which adjoins the top cooler 2 in FIG. 1, contains a ceramic layer 7, which on one surface side is provided with a continuous metallization 8 and on the other surface side also is provided with a structure metallization 9 forming strip conductors, contact surfaces, etc.

In an analogous manner, the metal-ceramic substrate 5 consists of the ceramic layer 10, the bottom, continuous metallization 11 and the top, metallization 11 is structured for forming strip conductors, contact surfaces, etc.

Between the two metal-ceramic substrates 4 and 5 or between the two structure metallizations 9 and 12 are the components 6 and with these, the electrical connections are connected thermally and electrically to the metallizations forming the components 6 in a suitable manner, namely for example by soldering.

The outer continuous metallizations 8 and 11 are full surface connected at least in a thermally conductive manner with the cooler 2 and 3 respectively, namely for example by means of a thermally conductive intermediate layer 13 and 14, which are respectively a solder layer, for example a soft solder layer, a layer of a thermally conductive adhesive or a thermally conductive paste. Principally, it is also possible to design the intermediate layers 13 and 14 so they are multi-layered, consisting of a solder intermediate layer on the cooler 2 and 3 and a solder layer or of an adhesive intermediate layer on the cooler 2 and 3 and a thermally conductive adhesive layer. If the intermediate layers 13 and 14 consist of a thermally conductive paste, then suitable measures, for example clamping devices, ensure that the two coolers 2 and 3 are in contact with and pressed against the top and bottom side of the module unit 16 by means of the intermediate layers 13 and 14.

The ceramic layers 7 and 10 are for example layers of Al₂O₃, Al₂O₃+ZrO₂, AlN, Si₃N₄ or a combination of one or more of the above ceramics.

The metallizations 8, 9, 11 and 12 are metallizations of copper, copper alloys, aluminum or aluminum alloys that are applied by means of suitable bonding processes, for example using the direct bonding or active bonding process or using an adhesive to the respective ceramic layer, or metallizations manufactured using thick film technology.

The electrical connections (terminals), in particular the power connections for the unit 1, are preferably provided only on one of the two metal-ceramic substrates, i.e. in the depicted embodiment on the metal-ceramic substrate 4, by leading out of the corresponding metallization 9 or also of a separate lead or connection 15 respectively, which is connected in a suitable manner with the structured metallization 9 and for example is formed by punching from a leadframe.

The two metal-ceramic substrates 4 and 5 and the components 6 provided between the former form a module, which is generally designated 16 in FIG. 1 and in the practical embodiment is compound-filled with an electrically insulating sealing compound, especially in the manner that this sealing compound completely fills all hollow spaces existing between the metal-ceramic substrates 4 and 5 and the components 6, that only the electrical connections 15 protrude laterally from the compound-filled module 16 and the metallizations 8 and 11 are exposed for the thermal connection to the coolers 2 and 3.

The electric unit 1 features the advantage of effective double-sided cooling of the module 16 and of the components 6, i.e. cooling both on the top side and on the bottom side. Since the module 16 is provided between the two coolers 2 and 3, the electric unit 1 can also be referred to as a thermal interface module.

It was assumed above that the external connections 15 are formed by leads connected with the structured metallization 9 or with metal surfaces provided there. FIGS. 2-5 show respectively simplified representations in cross section of further possible embodiments of the external connections 15a-15d in the manner that the ceramic layer 7 leads with at least one metallization forming the corresponding connection out of the housing of the module 16 formed by the sealing compound.

The connection designated 15a in FIG. 2 is formed by the lower structured metallization 9 and a metal surface 17 produced by structuring of the upper metallization 8 and by a through-hole 18 connecting the metallization 9 and the metal surface 17 in the proximity of an opening in the ceramic layer 7. This makes it possible to establish the external electrical connection to the connection 15a without the danger of the ceramic layer 7 breaking, by clamping to the sides of the metallization 9 and of the metal layer 17 facing away from each other, the through-hole contact 18 serving not only to establish an electrical connection, but simultaneously also as a mechanical support.

FIG. 3 shows as a further embodiment a connection 15b, which differs from the connection 15a only in that a breaking point 19 is provided in the ceramic layer 7 outside of the housing of the module 16 formed by the sealing compound, so that in the case of forces applied to the connection 15b exceeding the breaking strength of the ceramic layer 7 cause the ceramic layer 7 to break in a non-critical area, namely at the breaking point 19.

The connection 15c depicted in FIG. 4 differs from the connection 15b essentially in that instead of the breaking point 19 in the ceramic layer 7, a slot 19.1 is made, so that external forces applied to the connection 15c exceeding the breaking strength of the ceramic layer 7 cannot cause the ceramic layer 7 to break.

Finally, FIG. 5 shows a connection 15d, which differs from the connections 15b and 15c in that one of the metal surfaces, for example the upper metal surface 17, and the through-hole contact 18 have been eliminated. In principle, however, the upper metallization 17 could be present in the embodiment of FIG. 5.

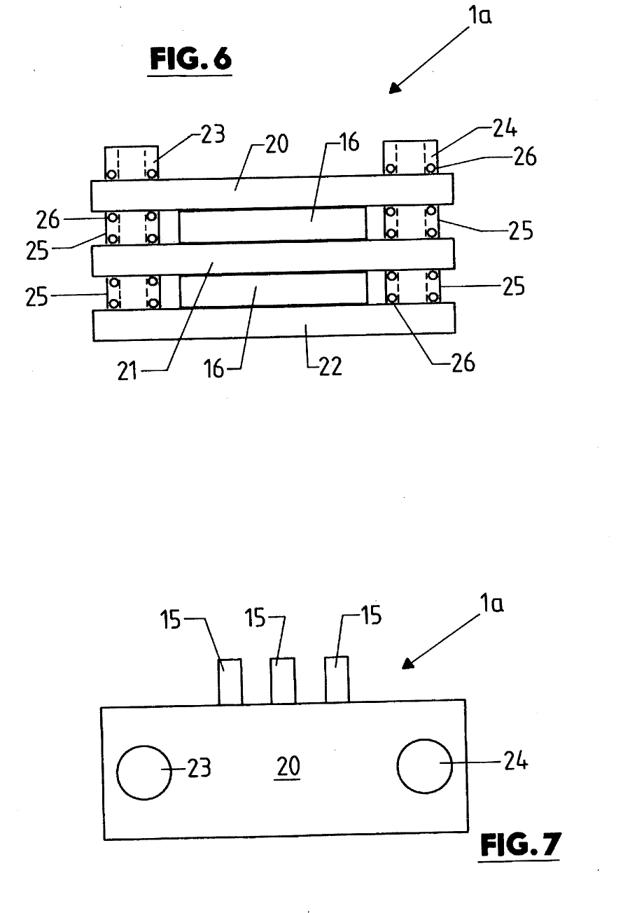

FIGS. 6 and 7 show as a further embodiment an electric unit 1a, which differs from the electric unit 1 first in that a total of three coolers 20-22 and two modules 16 are provided, so that the coolers 20-22 and modular units 16 provided between said coolers form a stack-like arrangement or cooler structure, so that each module 16 with its top and bottom side is thermally connected with a cooler 20 and 21 or 21 and 22, respectively, by means of an intermediate layer.

The coolers 20-22 are flat, plate-shaped and active coolers, i.e. coolers through which a coolant can flow. For supply of the coolant, connections 23 and 24 are provided on the top side of the unit 1a, which (connections) together with openings in the coolers 20-22 and in spacers 25 separating the coolers 20-22 form distribution channels for the supply and return flow of the coolant. The transitions between the coolers 20-22 and the connections 23 and 24 or the spacers 25 are sealed toward the outside by O-rings or sealing rings 26. The single elements are clamped and/or connected with each other by connecting or clamping means not further depicted to form the unit 1a and the cooler structure comprising the coolers 20-22. In principle it is also possible to manufacture the cooler structure formed by the coolers 20-22, the connections 23 and 24 and the spacers 25 compactly by soldering or another suitable manner.

The unit 1a features the advantage of double-sided and therefore very intensive and effective cooling of the modules 16.

In the embodiment depicted in FIGS. 6 and 7 the flat coolers 20-22 are rectangular in design when viewed from above. The connections 23 and 24 and the channels formed by these connections, the spacers 25 and the openings in the coolers 20-22 are provided on a narrow side of the rectangular coolers 20-22 or of the cooler structure. The electrical connections, which are designated 15 in FIG. 7, lead outward on one or also on both longitudinal sides of the cooler structure, which is rectangular when viewed from above.

The coolers 2, 3 and 20-22 consist of a metal material, e.g. copper or a copper alloy or aluminum or an aluminum alloy, and can be designed in many different ways with respect to their inner cooler structure through which the coolant flows. For example, the coolers consist of several surface connected plates of the same metal material, the inner plates being structured for forming micro or micro-cooling channels or cooling channels, namely if necessary also with posts connecting the top side and bottom side of the respective cooler and around which the coolant flows, the posts having additional wing-like cooling surfaces, etc. extending into the coolant flow.

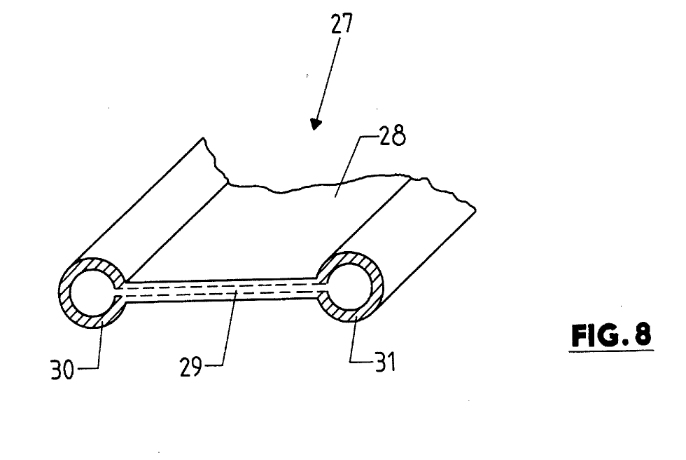

FIG. 8 shows in a very schematic representation a flat, plate-shaped active cooler 27, which can be used instead of the coolers 2 and 3 and 20-22 and is manufactured economically using a flat profile of a metal material. The cooler 27 consists essentially of a square or rectangular plate 28 produced from the flat profile, in which (plate) several cooling channels 29 are formed, extending from a circumferential side to the opposite circumferential side, already provided in the flat profile and through which the coolant can flow. For the supply and return flow of the coolant there are two lengthwise slotted pipe sections 30 and 31, into which the plate 28 extends with its sides comprising the openings of the cooling channels 29 and with which the plate 28 is tightly connected on these sides, so that the coolant can flow through the pipe section 30 or the interior of this pipe section into the cooling channels 29 and can flow through the pipe section 31 or through the interior of this pipe section out of the cooling channels 29.

In order to form a cooler structure in which two coolers 27 are provided with their plates 26 separated from one another and parallel to one another for holding at least one module 16 between these plates 28 and for two-sided cooling of the module 16, the pipe sections of the at least two coolers 27 are closed on one end and on the other end are connected with a common channel for the supply and return flow of the coolant.

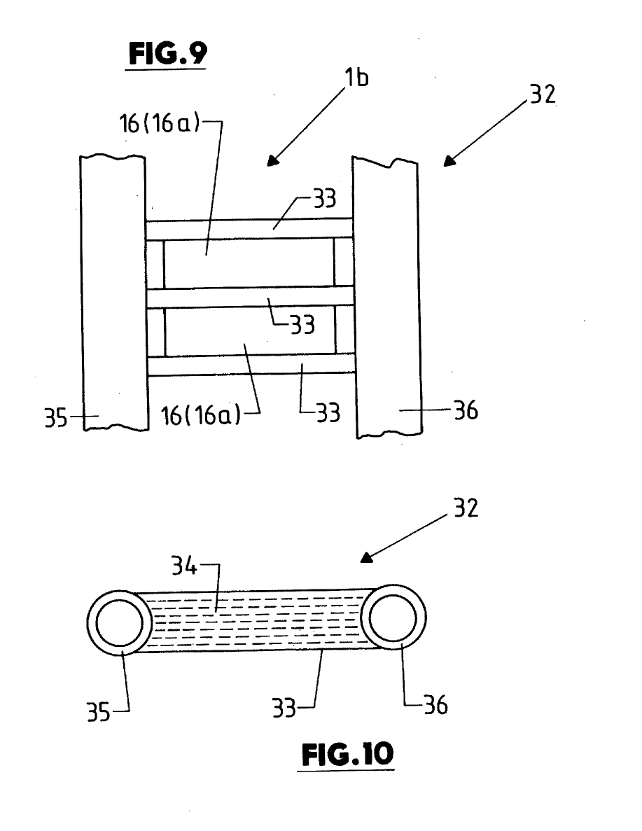

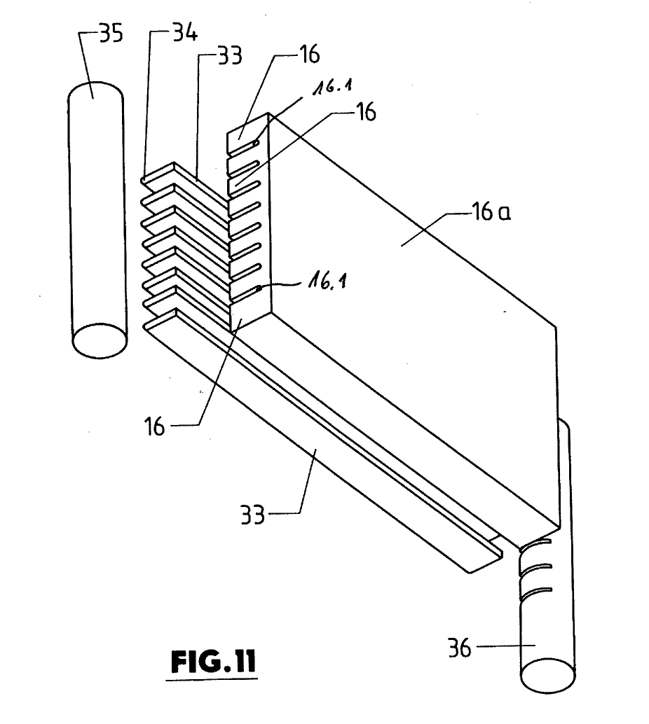

FIGS. 9-11 show in a simplified depiction a cooler structure, generally designated 32 in these figures, of an electric unit 1b, which (cooler structure) consists of several flat, plate-shaped coolers 33, which are provided parallel to one another and separated from one another for holding and two-sided cooling of at least one module 16 between two coolers 33, respectively. The plate-shaped and, when viewed from above rectangular coolers 33 are in the simplest case metal plates, for example such plates of copper, a copper alloy, aluminum or an aluminum alloy, preferably manufactured from a flat profile, which is manufactured with a plurality of channels on the inside. These channels form the cooling channels 34, which extend in the case of each cooler 33 from a plate edge to the opposite plate edge and are open on these plate edges. On the plate edges, on which the cooling channels 34 are open, the coolers 33 extend respectively through a rectangular slot into pipe sections 35 and 36 and are tightly connected there with the pipe sections, so that an outwardly sealed connection between the pipe sections 35 and 36 and the coolers 33 is achieved for the supply and return flow of the coolant. The two pipe sections 35 and 36 are provided with their axes parallel to one another and separated from one another and also perpendicular to the plane of the top and bottom side of the coolers 33.

For the manufacture of the electric unit 1b, which comprises at least two coolers 33, preferably more than two coolers 33 and modules 16 inserted between two coolers 33 respectively, first the cooler structure 32 formed by the coolers 33 and the pipe sections 35 and 36 is manufactured and afterwards post-worked so that the distance between the mutually opposing coolers 33 corresponds exactly to the thickness of the modules 16, i.e. exactly to the distance between the outer surfaces of the outer metallizations 8 and 11. This post-working of the cooler structure 32 is achieved by corresponding upsetting of the pipe sections 35 and 36 in their axial direction. For this purpose, end blocks, i.e. formed sections of a suitable material, e.g. of metal, are then inserted between the coolers 33, the thickness of which corresponds exactly to the thickness of the modules 16 and which therefore determine the distance between the coolers 33 during upsetting of the pipe sections 35 and 36. Afterwards, the end blocks are removed, so that the modules 16 can then be mounted between the single coolers 33.

It was assumed above that the cooling channel structure of the flat, plate-shaped coolers 33 is formed by a plurality of cooling channels 34. Of course, other cooling channel structures are also possible. In particular, it is also possible to manufacture the coolers 33 so they are multi-layered, of several surface connected metal coats or layers, the inner metal coats or layers then being structured or provided with openings for forming a multiply branching inner cooling channel structure.

It is possible to mount the modules 16 singly in the space respectively between two adjacent coolers 33, or to connect the modules 16 with each other to form a chamber-like modular unit 16a, which then is pushed or placed laterally onto the cooler structure 32 formed by the coolers 33 and the pipe sections 35 and 36. The chamber-like modular unit 16a consists of several modules 16. The mutually separated modules 16 are connected with each other on one of their longitudinal sides. On the other longitudinal side the spaces formed between the modules 16 are open, so that the modular unit 16a can be placed with this side ahead laterally onto the coolers 33 extending in a ladder rung-like manner between the pipe sections 35 and 36, which makes it possible to mount a plurality of modules 16 on the cooler unit 32 in an especially simple manner.

The chamber-like modular unit 16a is designed with respect to its outer shape as a cube-shaped block, which is provided on one side with a plurality of grooves 16.1 that are open on this side and on two mutually opposing front faces, which (grooves) extend parallel to one another and at a distance from one another and in the depicted embodiment also parallel to two circumferential sides of the block. A module 16 is provided respectively on both sides of each groove 16.1. In the area of the closed side of the block, electrical connections for example extend within the block.

Especially for applications in automotive construction and also in the immediate proximity or on motor blocks generally manufactured from aluminum or an aluminum alloy the coolers 2, 3, 27, 33 and cooler structures as well as their further elements are manufactured from aluminum or an aluminum alloy, namely to avoid corrosion caused by the combination of different metals.

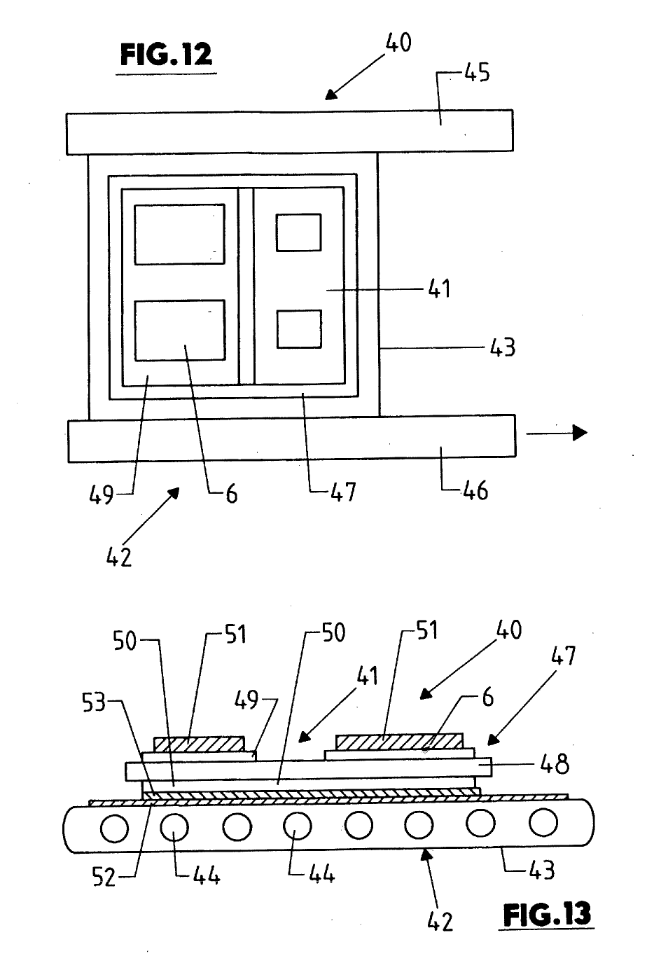

FIGS. 12 and 13 show as a further embodiment of the invention a cooled electronic unit 40 with an electric or electronic module 41 and a flat, plate-shaped cooler 42. The latter consists of a flat and, in the depicted embodiment, essentially square cooling plate 43 formed from a flat profile with a plurality of cooling channels 44, which likewise extend from a plate edge to the opposite plate edge, are open on this plate edge and are formed by cooling channels already existing in the flat profile. Two pipe sections 45 and 46 are used for the supply and return flow of the coolant, between which the cooling plate 43 is provided and which are parallel with their axes to one another and separated from each other. The two pipe sections 45 and 46 are fastened to the cooling plate 43 so that the cooling channels 44 lead tightly sealed into the channels formed in the pipe sections 45 and 46, respectively. In the depicted embodiment the pipe section 45 is used for supply of the coolant and the pipe section 46 is used for the return flow. The cooling channels 44 are offset parallel to the surface sides of the cooling plate 43, but can additionally be mutually offset in the direction of the plate thickness. Of course, the cooling plate 43 can also have another shape.

The electric or electronic module 41 is provided on the top side of the cooling plate 43. Said module consists essentially of a metal-ceramic substrate 47 with a ceramic layer 48 and with metallizations 49 and 50 on both surface sides of the ceramic layer 48. The metallization 49 on the top side is structured for forming conductors, contact surfaces, etc. The metallization 50 on the bottom side is designed to be continuous. Electric components, for example semiconductor components 51, also at least one power component, are provided on the metallization 49.

With the metallization 50 the electronic module 41 is connected mechanically and especially also thermally with the cooling plate 43. For this purpose the cooling plate 43 in the depicted embodiment is provided on its top side with a solder intermediate layer 52, on which the metal-ceramic substrate 47 with the metallization 50 is then fastened by soldering or by a solder layer 53. In principle, it is also possible to fasten the metal-ceramic substrate 47 or the electric module 41 on the cooling plate 43 using a thermally conductive adhesive, in which case the solder intermediate layer 52 is then dispensed with and a layer of the thermally conductive adhesive is provided instead of the solder layer 53.

Especially for applications in automotive construction and also especially in the immediate proximity or on motor blocks generally manufactured from aluminum or an aluminum alloy the cooler 42 and especially also the cooler plate 43 are manufactured from aluminum or an aluminum alloy, namely to avoid corrosion caused by the combination of different metals.

The ceramic of the ceramic layer 48 of the electric module 41 is Al₂O₃, AlN, Si₃N₄ or Al₂O₃+ZrO₂. In principle, combinations of these can also be used. The thickness of the ceramic layer 48 is for example between 0.15 and 2.0 mm. The metallization 49 consists of copper or a copper alloy and has a thickness of approximately 0.012-0.8 mm. The metallization 50 consists of Ag, Ag—Pd, Ag—Pt and has a thickness of approximately 0.01-0.09 mm. The solder intermediate layer 52, if present, consists of Ni, Cu, NiP and is applied for example galvanically, by cold gas spraying, by plasma spraying or by flame spraying.

The solder intermediate layer is applied only where the metal-ceramic substrate 47 is to be fastened by soldering. In principle it is also possible to provide the solder intermediate layer 52 on the entire top side of the cooler 42 or of the cooling plate 43.

Insofar as the connection between the electric module 41 and the cooling plate 43 is achieved using a thermally conductive adhesive, it is expedient to provide an adhesive intermediate layer to the top side of the cooling plate 43 at least where the connection is to be made, for example of Al₂O₃ with a thickness of approximately 0.01-0.1 mm and produced by anionic oxidation.

The solder layer 53 has a thickness of 0.02-0.5 mm. Suitable solders are Sn alloys or also layers of Ag (pressure sintered at 200-400° C.). Preferably a metal material with a thermal expansion coefficient of 7-12 ppm, for example CuW or CuMo, is used for the solder intermediate layer.

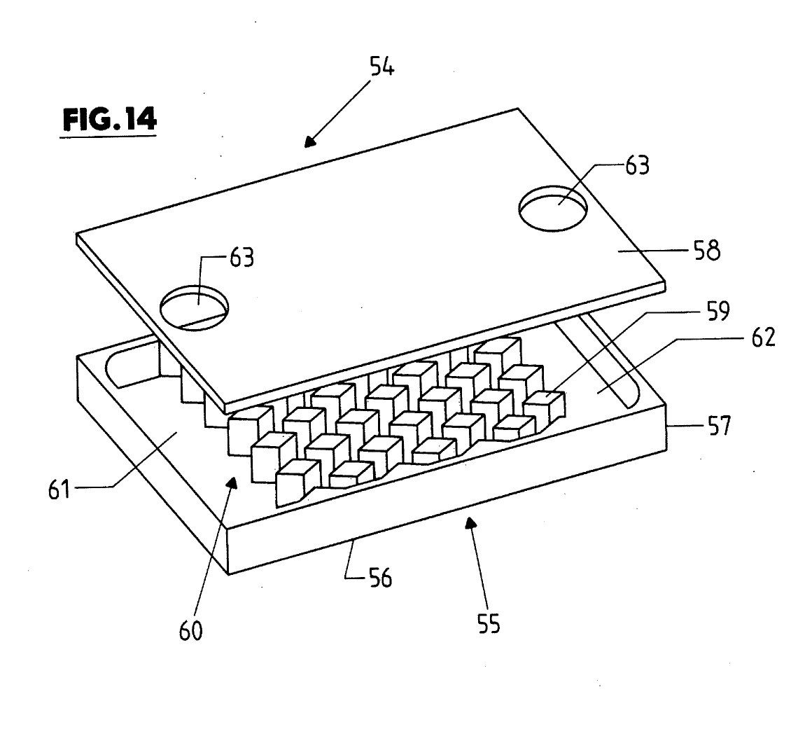

FIG. 14 shows a simplified perspective exploded view a cooler 54 consisting of a flat, tub-shaped bottom part or cooler element 55 with a bottom 56 and circumferential edge 57 and of a cover 58 placed on the open side of the cooler element 55. In the depicted embodiment the cooler 54 and its cooler element 55 and cover 58 are rectangular when viewed from above. On the inner surface of the bottom 56, projections 59 are formed on and which in the depicted embodiment have a diamond-shaped cross section and are provided in several mutually offset interrupted rows parallel to the longer circumferential sides of the cooler element 55. The projections 59, which are separated from each other and therefore form flow channels between them for the coolant flowing through the cooler 54 and with the larger diagonal of their diamond shape are oriented parallel to the longer circumferential sides of the cooler element 55, form a cooler structure 60, which ends in the area of the two narrow sides of the cooler element 55 at a distance from the respective narrow side. Between each narrow side and the cooler structure 60 a chamber 61 and 62 is therefore formed in the interior of the closed cooler 54, the chamber 61 being used for example for the supply and distribution of the coolant to the cooler structure 60 and the chamber 62 being used to collect the coolant after flowing through the cooler structure 60. The two chambers 61 and 62 can be connected to an external coolant circuit by means of connections or openings 63, which in the depicted embodiment are provided in the cover 56. In the case of a closed cooler 54 the projections 59 extend respectively to the inner side of the cover 58, where they are preferably connected with the cover.

The cooler 54 or its cooler element 55 and/or cover 56 are manufactured from a metal material, e.g. copper, a copper alloy, aluminum or an aluminum alloy, the cooler element 55 being manufactured by casting or milling. In principle it is also possible to manufacture the cooler element 55 from copper using DCB technology, namely from a plate forming the bottom 56, from a frame forming the edge 57 and from pre-formed bodies forming the projections 59.

It is further possible to manufacture the cooler 54 and thereby especially its cooler element 55 from a plastic, for example from epoxy resin and thereby preferably from plastic with at least one additive to increase the thermal conductivity with graphite or with carbon nanofibers or nanotubes.

The connection of the cover 54 with the cooler element 55 is based on the material used for the cooler 54 by DCB technology, by soldering or by adhesive bonding.

On the cooler 54 and thereby preferably on the bottom side of the cooler element 55 facing away from the openings 63 at least one electric module, the electric module 41, is mounted, namely in the same manner as described above in connection with FIGS. 12 and 13.

The cooler 54 forms a cooling surface respectively on the mutually opposing sides. It is further possible to provide the cooler 54 multiply in an electric unit, in which case then between the coolers electric components or modular units or modules with the coolers 54 are provided respectively in a stack.

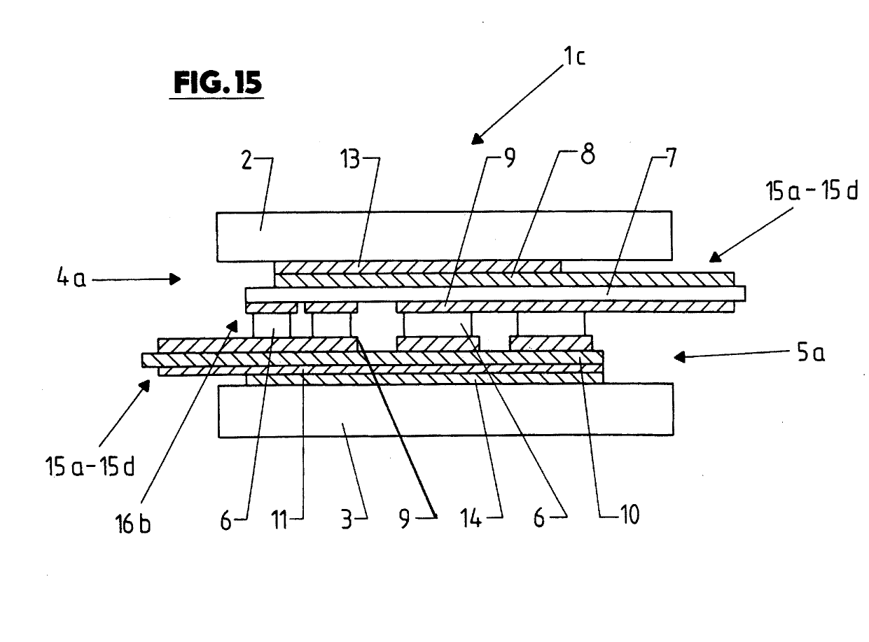

FIG. 15 shows in a depiction similar to FIG. 1 an electric unit 1c, which comprises the two external coolers 2 and 3, the two metal-ceramic substrates 4a and 5a corresponding to the metal-ceramic substrates 4 and 5, which are connected with the coolers 2 and 3 by the intermediate layer 13 and 14 respectively, and the electric components 6. The unit 1c differs from the unit 1 essentially in that for forming the electrical connections, at least the ceramic layers 7 and 10 lead out of the modular unit 16b on the side at least with the inner metallization 9 and 12. The electrical connections are embodied in detail corresponding to the connections 15a-15d.

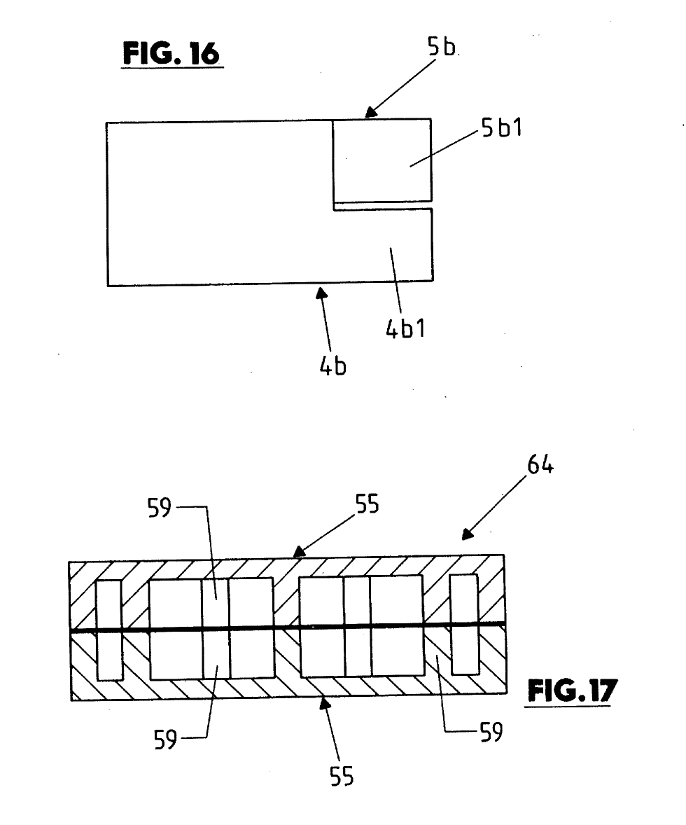

FIG. 16 shows a modular unit 16c, in which the ceramic layers of the substrates 4b and 5b corresponding to the metal-ceramic substrates 4 and 5 are provided on an edge area with a section 4b1 and 5b1 projecting over this edge area, namely so that the section 4b1 is offset from the section 5b1 so that in the top view in FIG. 16 both sections are visible. The metallizations provided on the ceramic layers are also embodied accordingly. On the sections 4b1 and 5b1 these metallizations form the external connections, namely in an embodiment corresponding to the connections 15a-15d.

FIG. 17 shows in a simplified cross section view a flat cooler 64, which consists of two tub-shaped cooler elements 55, which adjoin each other with their opening side and are tightly connected with each other. In the outwardly closed interior space of the cooler 64 formed by the two tub-shaped cooler elements 55 the projections 59 are arranged so that each projection 59 on a cooler element 55 adjoins a projection 59 on the other cooler element 55. Preferably the projections 59 are thermally connected with other by suitable means using a thermally conductive adhesive, by soldering or in another suitable manner.

The cooler 64 forms a cooling surface respectively on the mutually opposing sides. It is further possible to provide the cooler 64 multiply in an electric unit, in which case then between the coolers 64 electric components or modular units or modules with the coolers 64 are provided respectively in a stack.

Insofar as the electric components or units are connected by means of a connecting layer or several connecting layers by means of a solder layer, with the respective cooler or its cooler element, with the cooler 2, 3, 20-22, 33, 54 or 64, it is expedient to embody the wall thickness of the wall of the cooler adjoining the connecting or solder layer so that it is very thin, namely so thin that mechanical tensions due to temperature changes, especially of the cooler, are compensated by the elasticity of the thin wall of the cooler and therefore still within the cooler and therefore are not transferred to the connecting or solder layer. This embodiment of the invention is based on the knowledge that temperature-related mechanical tensions or mechanical tensions generated by fluctuations of temperature can be absorbed and compensated by the thin wall of the cooler consisting of metal significantly better and without detriment to the material quality and/or stability than is the case in the adjoining connecting or solder layer, which rather tends to be destroyed by temperature-related changing mechanical tension. With this embodiment, the life of an electric unit can be significantly improved. The thickness of the wall of the cooler adjoining the connecting and/or intermediate layer is then, in the case that the cooler is made of metal, for example of copper or aluminum, preferably between 0.2 mm and 1.5 mm.

The invention was described above based on exemplary embodiments. It goes without saying that further modifications and variations are possible, without abandoning the underlying inventive idea upon which the invention is based.

### REFERENCE LIST

1, 1a, 1b, 1c electric unit

2, 3 cooler

4, 5 metal-ceramic substrate

4a, 5a, 4b, 5b metal-ceramic substrate

4b1, 5b1 projection

6 electrical component, semiconductor component

7 ceramic layer

8.9 metallization

10 ceramic layer

11, 12 metallization

13, 14 intermediate layer

15, 15a-15d external electrical connection

16 module or modular unit

16a chamber-like modular unit

16b, 16c module or modular unit

16.1 grooves

17 metal surface

18 through-hole contact

19 breaking point

19.1 slot

20, 21, 22 cooler

23, 24 connection for coolant

25 spacer

26 seal ring

27 cooler

28 plate-shaped cooling element

29 cooling channel

30, 31 pipe section

32 cooler unit

33 cooler or cooling element

34 cooling channel

35, 36 pipe section

40 electric unit

41 electric module

42 cooler

43 cooling plate

44 cooling channel

45, 46 pipe section

47 metal-ceramic substrate

48 ceramic layer

49, 50 metallization

51 electric component

52 solder intermediate layer

53 solder layer

54 cooler

55 tub-shaped bottom element or cooler element

56 bottom

57 edge

58 cap

59 projection

60 cooler structure

61, 62 chamber

63 opening

64 cooler

1. (canceled)

2. An electric unit with at least one ladder rung-like cooler structure, the electric unit comprises at least three flat active coolers, which extend parallel to each other and at a distance from each other between pipe sections for a supply and return flow of a coolant,
wherein between two of the coolers respectively a module with at least one electric component is provided, which is connected at least thermally with both mutually adjacent coolers on two mutually opposing sides of the module,
wherein the module comprises at least two metal-ceramic substrates, which consist of at least one ceramic layer respectively, which are provided on at least one surface side with a first metallization that is at least partially structured, and with a side facing away from the first metallization connected at least thermally with one of the two coolers,
that the at least one electric component is provided between the two metal-ceramic substrates of the module and is connected electrically with the first metallization of the at least two metal-ceramic substrates and is thermally connected with the first metallizations of both substrates, and
two modules are connected to form a chamber-like modular unit that can be pushed onto the coolers of a cooler structure.

3-9. (canceled)

10. The electric unit according to claim 2, wherein the cooler structure comprises three coolers, which are arranged parallel to one another and at a distance from one another, and between two of the coolers at least one module is provided which is connected at least thermally with both adjacent coolers on two mutually opposing sides of the module.

11. The electric unit according to claim 10, wherein the three coolers are connected with each other by means of spacers, and openings provided at least in some spacers complement openings in the three coolers to form channels for the supply and return flow of the coolant.

12. The electric unit according to claim 10, wherein the three coolers forming the cooler structure are multi-layered, consisting of several plates connected with each other.

13. The electric unit according to claim 10, wherein the three coolers are formed at least partially from plates of a flat profile with a plurality of the cooling channels.

14-15. (canceled)

16. The electric unit according to claim 2, wherein the coolers are flat, plate-shaped coolers.

17. (canceled)

18. The electric unit according to claim 2, wherein the coolers of the cooler structure are identical.

19-36. (canceled)

37. The electric unit according to claim 2, wherein the first metallization is made of copper, copper alloy, aluminum, aluminum alloy and has a thickness of 0.012-0.8 mm.

38. The electric unit according to claim 2, wherein the first metallization is selected from one or more layers of Ag, Ag—Pd, Ag—Pt, W/Ni, Mo—Mn/Ni and has a thickness of 0.01-0.9 mm.

39-43. (canceled)
